(19) United States
(12) Patent Application Publication
(10) Pub. No.: US 2026/0149269 A1
(43) Pub. Date: May 28, 2026

(54) ESD PROTECTION OF TRANSCEIVER ANTENNA PIN

(71) Applicant: NXP B.V., Eindhoven (NL)

(72) Inventors: Marcin Grad, Emmerich am Rhein (DE); Houssam Arbess, Nijmegen (NL); Viet Thanh Dinh, Austin, TX (US); Brian Jacob Nissim, Baltimore, MD (US)

(21) Appl. No.: 18/956,418

(22) Filed: Nov. 22, 2024

(51) Int. Cl. H02H 9/04; H01Q 23/00

(52) U.S. Cl. CPC H02H 9/046; H01Q 23/00; H10D 89/611; H10D 89/811

(57) ABSTRACT

Disclosed is an ESD-protected, isolation circuit comprising: an isolation switch; an inductive coupler in series therewith; an antenna terminal, connected to a ground via the isolation switch and the inductive coupler in series, the inductive coupler being configured to, in response to the switch being in an on-state, provide inductive coupling to a transmitter circuit, and wherein the switch is configured to, in an off-state, galvanically isolate the inductive coupler from the antenna terminal; and a protection circuit, wherein the protection circuit comprises: a first inductive current path connected between the antenna terminal and ground, and a second current path connected in parallel to the switch and between the antenna terminal and the inductive coupler, wherein, the second current path is enabled in response to an ESD event at the antenna terminal. Other embodiments are disclosed.

### FIELD OF THE DISCLOSURE

The present disclosure relates to method and circuit for protecting against electrostatic discharge (ESD) events. In particular, it relates to electrostatic discharge events associated with antenna terminals, which may be connected or connectable to transmitter or transceiver circuits.

### BACKGROUND

Some semiconductor integrated circuits utilize electrostatic discharge (ESD) devices for discharging charge from an ESD event affecting a die terminal. An ESD event may occur for example when a charged object (e.g., a human finger) inadvertently contacts a conductive surface of an integrated circuit die (e.g., a contact pad or other die terminal) or a conductive surface of an integrated circuit package coupled to the pad where charge at an elevated voltage is applied to the conductive surface due to the contact. Being at an elevated voltage, such charge may cause voltage differentials across the devices of the integrated circuit that may exceed their safe operating area voltages and damage those devices. An ESD event may also occur when a charged conductive surface of a circuit contacts an external object where charge is transferred between the conductive surface and the external object.

### SUMMARY

According to a fist aspect of the present disclosure, there is provided an electrostatic-discharge-protected, ESD-protected, isolation circuit comprising: an isolation switch; an inductive coupler in series with the isolation switch; an antenna terminal, connected to a ground via the isolation switch and the inductive coupler in series, wherein the inductive coupler is configured to, in response to the switch being in an on-state, provide inductive coupling to a transmitter circuit, and wherein the switch is configured to in an off-state, galvanically isolate the inductive coupler from the antenna terminal; and a protection circuit, wherein the protection circuit comprises: a first inductive current path connected between the antenna terminal and ground, and a second current path between the antenna terminal and the inductive coupler, wherein the second current path is enabled in response to an ESD event at the antenna terminal. Typically the second current path is connected in parallel to the switch alone, but in some embodiments, it could be connected in parallel with the switch and other components (such as a capacitor). Providing the second current path may improve the ESD protection, since the inductance in the first current path may result in a relatively high impedance on the occurrence of certain (high frequency in particular) ESD events.

In one or more embodiments, the second current path comprises at least one pair of diodes connected in anti-parallel. Such an implementation may avoid interfering with normal operation of the circuit (that is to say, operation of the circuit. In the absence of an ESD event). In one or more embodiments, the at least one pair of diodes connected in anti-parallel comprises a series arrangement of plurality of pairs of diodes, connected in anti-parallel. There may or may no be a respective electrically common node between any of the pairs of diodes.

The circuit may further comprise: a first capacitor connected between the antenna terminal and the switch; and a second capacitor connected between the switch and the inductive coupler.

In one or more embodiments, the at least one pair of diodes connected in anti-parallel is connected across a path comprising the first capacitor, the switch and the second capacitor. In one or more embodiments, the at least one pair of diodes connected in anti-parallel is connected in series with, and between, the first capacitor and the second capacitor. In one or more embodiments, the at least one pair of diodes connected in anti-parallel is configured to conduct at a voltage which is less than a break-down voltage of the switch. In one or more embodiments, the at least one pair of diodes connected in anti-parallel is configured to conduct a current such that a current through the switch is less than a break-down current of the switch.

The first inductive current path may comprise: a further inductive coupler connected to between the ground and a first node, A, and a series arrangement of two inductors having a second node B therebetween and being connected between the further inductive coupler and the antenna terminal; wherein the further inductive coupler is configured to be inductively coupled to a receiver circuit; and wherein the ESD-protected isolation circuit further comprises a shunt switch connected between the node and ground, and configured to bypass the further inductive coupler in response to the isolation switch being in the on-state.

In one or more embodiments, the inductive coupler is a balun. In one or more embodiments, the isolation switch is a field effect transistor, FET. In such embodiments, the isolation switch may be a fully depleted semiconductor-on-insulator FET, in a technology node which is no greater than 22 nm; without limitation, the isolation switch may alternatively be a FinFET, in a technology node which is no greater than 16 nm. The above process technology nodes are examples of technology nodes which may be described as advanced technology nodes, at the time of writing of the present disclosure.

In one or more embodiments, the first inductive current path and the second current path are the only ESD current paths to ground. Such embodiments may thereby avoid voltage clipping of a transmitted signal, which could, in some applications, otherwise occur as a result of other ESD current paths.

In one or more embodiments, the first inductive current path is coupled to a receiver circuit. In such embodiments, the isolation switch may provide isolation between the receiver circuit and the transmitter circuit, and avoid noise from the transmitter circuit interfering with any received signal in the receiver circuit. In one or more such embodiments, the receiver circuit is a single-ended circuit and the first inductive current path includes a low-noise amplifier (LNA) which is a part of the first inductive current path. Alternatively and without limitation, the LNA could be coupled to the first inductive path by a transformer, or the receiver circuit could be a differential circuit wherein first inductive current path is coupled to the receiver circuit by a balun, being part of the first inductive current path. In other embodiments, the isolation switch may provide isolation between the transmitter circuit and another circuit in place of or in addition to the receiver circuit.

### BRIEF DESCRIPTION OF THE DRAWINGS

Reference will now be made to the accompanying drawings, which are not necessarily drawn to scale, and wherein:

FIG. 1 shows an ESD-protected isolation circuit according to one or more embodiments of the present disclosure;

FIG. 2, FIG. 3 and FIG. 4 each shows simplified circuit corresponding to part of the circuit of FIG. 1, according to one or more embodiments;

FIG. 5 shows a schematic circuit diagram of an isolation switch according to one or more embodiments, and

FIG. 6 shows a schematic cross-section through the isolation switch.

It should be noted that the FIG. s are diagrammatic and not drawn to scale. Relative dimensions and proportions of parts of these FIG. s have been shown exaggerated or reduced in size, for the sake of clarity and convenience in the drawings. The same reference signs are generally used to refer to corresponding or similar features in modified and different embodiments.

### DETAILED DESCRIPTION

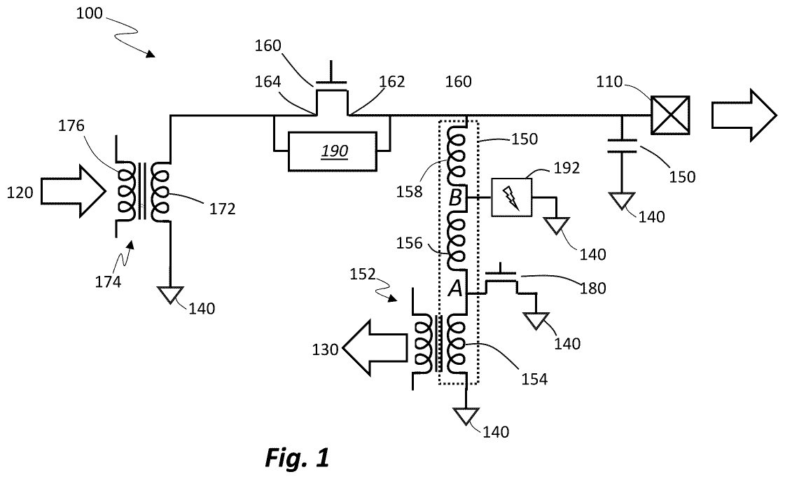

FIG. 1 shows an electrostatic-discharge-protected, ESD-protected, isolation circuit according to one or more embodiments of the present disclosure. The circuit includes a terminal, contact pad or pin, which may be referred to as an antenna terminal 110. The antenna terminal may be connected to an antenna for sending and receiving radio frequency, RF, signals. Relatively high-power and high voltage signals may be routed from a transmitter 120 to an antenna (not shown) through the antenna terminal 110. Moreover, relatively low power or low voltage signals may be routed from the antenna to a receiver 130 through the antenna terminal 110. The antenna terminal may be directly capacitively coupled to a ground 140 through an capacitance 150. The skilled person will appreciate that the capacitance 150 may be provided as a dedicated component, or may exist as a parasitic capacitance.

The antenna terminal is connected to ground 140 by a first inductive current path 150. The first inductive current path 150 is used to receive a signal from the antenna and route it to the receiver 130. As will be described in more detail hereinbelow, the first inductive current path 150 provides, or is associated with, a first ESD discharge path from the antenna terminal 110 to ground 140.

Antenna terminal 110 is connectable to the transmitter circuit 120 by means of isolation switch 160. Isolation switch has one main terminal 162 connected to the antenna terminal 110, and a second main terminal 164 connected to a first terminal of a first coil 172 of an inductive coupler 174. The second terminal of the first coil 172 of the inductive coupler 174 is connected to ground 140 as shown. Isolation switch 160 is typically implemented as a MOSFET, as will be described in more detail hereinbelow.

When the insolation switch 160 is closed or in an on-state, it provides galvanic electrical connection between the antenna terminal and the inductive coupler 174. The inductive coupler 174 may be also be referred to as a balun and is typically implemented as a transformer with the first coil 172 and a second coil 176. Those skilled in the field of RF communication will be aware that a balun is generally a component which provides a transition from a balanced signal to an unbalanced signal (balanced-unbalanced). For example, the transmitter circuit 120 may provide a relatively high-power output signal which is a balanced or differential signal. The signal is transitioned to a single ended or unbalanced signal, referenced to the ground 140 and output from the antenna via the isolation switch 160 and antenna terminal 110.

In RF circuits, such as transceivers, as has already been mentioned, the transmitted signal may be high-power or high voltage, and consist of an oscillating signal which typically may include voltage excursions of up to 10V or more. In contrast, the signals received at the antenna for processing by the receiver 130 may be four to twelve orders of magnitude lower in power, and around six orders of magnitude lower in voltage, being typically a few mV, or even less. In order to avoid adding noise to, or otherwise degrading, the low power received signal, it may be required to isolate the transmitter circuitry, and in particular the balun or inductive coupler 174, from the antenna terminal. Otherwise, the impedance of the circuit may significantly reduce the signal-to-noise ratio of the received low-power RF signal. The isolation switch 160 is configured to provide such isolation: when the transmitter 120 is active and a signal is to be transmitted from the antenna via the antenna terminal 110, the switch 160 is in an on-state, that is to say, closed in order to provide a low impedance path for the high-power transmitted signal. Conversely, when the transmitter is inactive, and in particular when the receiver 130 is operating, the isolation switch 160 is opened or in an off state to provide galvanic isolation between the transmitter circuitry, and in particular its capacitance, and the remainder of the circuit and in particular the antenna terminal which carries the relatively low power received signal.

As mentioned above, the circuit 100 include a first inductive current path 150 which is used to receive a signal from the antenna and route it to the receiver 130. The first inductive current path 150 may include a first coil 154 of a balun or inductive coupler 152. The balun or inductive coupler 152 is configured to transition the single ended or unbalanced signal received from the antenna through the antenna terminal 110 to a balanced or differential signal for processing in the receiver 130. In other embodiments, the path does not include a balun, but an alternative front-end part of a receiver circuit, such as, for example a low noise amplifier (not shown in FIG. 1).

As shown in FIG. 1, the first inductive current path 150 may include one or more further inductances 156, 158, as shown. The skilled person will appreciate that the inductances 156, 158 may be implemented as dedicated components (“inductors”) or may be provided by parasitic since. The coupling inductance may be arranged in series with the further inductances 156 and 158, with a node A therebetween, and the further inductances 156 and 158 are arranged in series with each other (having a node B therebetween as shown). There may be, as shown in FIG. 1, an ESD protection path from the antenna terminal 110 through the inductor 158, and an ESD protection device 192 (which may be implemented as, for example, a pair of diodes connected in antiparallel), to ground 140. In some embodiments (not shown in FIG, 1), this may form a part of, or the whole, of the first current path 150.

Embodiments of the present disclosure include circuitry to isolate the receiver 130 from the transmitted signal during transmit mode. One way of achieving this is illustrated in FIG. 1 by the inclusion of a shunt switch 180. Shunt switch 180 is arranged to provide a switchable path to shunt the first inductive coupler 152, and is connected between the node A and ground. When the circuit is in a receive mode, the shunt switch 180 is open or in an off state, such that the signal is routed through the inductive coupler 152. Conversely, when the circuit is in a transmit mode, the shunt switch 180 is closed or in on-state, thereby bypassing or shunting the inductive coupler 152 and isolating the receiver 130.

During an ESD event at the antenna terminal 110, the ESD charge may follow the first inductive current path 150 to ground. It will be appreciated that in the event that the shunt switch 180 is closed, some or all of the current will flow direct to ground through the switch rather than through the inductive coupler. The skilled person in the field of ESD protection will be aware that ESD events may have different time and charge profiles. One standardised ESD event model is the so-called human body model (HBM). HBM ESD events have relatively low frequency compared with some other types of ESD events. Because the charge is supplied over a relatively long period, often of the order of hundreds of nanoseconds, and typically 200-300 ns, the peak current is lower than may be the case in other types of ESD events. Since the current is relatively low, of the order of a few A (for example, it may be between 1 A and 2 A) and in particular since the rate of current increase is relatively low, the impedance provided by the first inductive current path 150 is relatively low and does not result in a significant voltage drop through the current path. For example, in a typical application the first coil 150 of the inductive coupler may have an inductance of approximately 1 nH, one or more further inductances 156 and 158 may each have an inductance of approximately 2 nH. The voltage drop across the first inductive current during an HBM ESD event may then be typically of the order of hundreds of millivolts up to a few volts (and typically less than 3V).

According to one or more embodiments of the present disclosure, protection against ESD events is provided not only by the first inductive current path, but includes a supplemental, or second, current path, from the antenna terminal 110 to the inductive coupler 172, and thence to ground 140. The second current path include circuit block 190, and is enabled in response to an ESD events at the antenna terminal. It may be enabled, and may be required, only when the isolation switch 160 is in an off state, that is to say, open. In other implementations, it may be enabled by the ESD event itself irrespective of the state of the isolation switch 160, in particular, for embodiments in which the isolation switch may not have a sufficient current-carrying capacity to handle the ESD event even when in an on-state.

As an alternative to providing the second current path through the inductive coupler, providing an ESD discharge path direct to ground could be considered. Such a discharge path could comprise a pair of diodes connected in antiparallel and directly between the antenna terminal 110 and ground 140. Alternatively, a plurality of such pairs of diodes connected and antiparallel could be considered. However, whilst this could provide protection against an ESD events and in particular a high frequency ESD event (that is to say an ESD event with a fast rise time of the current) it could result in clipping of a large voltage swing transmit signal. For example, a stack of four pairs of diodes, with a corresponding turn-on voltage of +/−3.2 V, would likely clip a voltage swing greater than 6.4 V peak-to-peak. This would be undesirable.

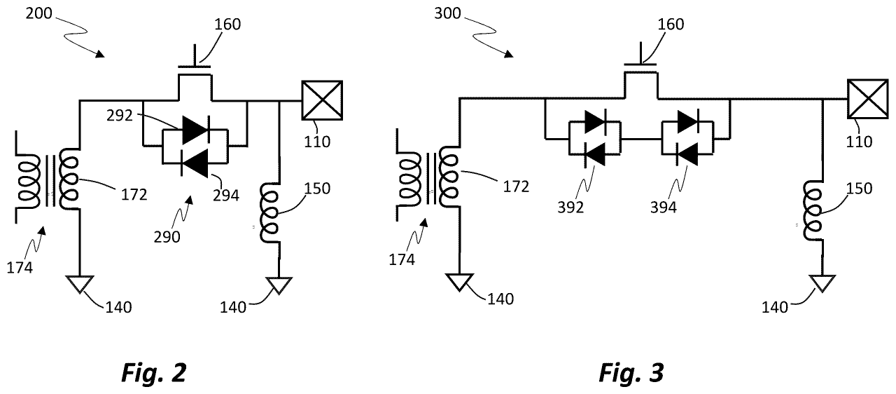

Returning to the FIG. s, one implementation of the circuit block 190 which forms the second current path is a pair of diodes connected in antiparallel. This is illustrated in FIG. 2, which shows a simplified circuit 200 corresponding to part of the circuit of FIG. 1, according to one or more embodiments. The FIG. shows the current path implemented as a pair of diodes 290, connected in antiparallel to and across the main terminals of the isolation switch 160. The diodes are connected in antiparallel such that the anode of a first diode 292 of the pair of diodes is connected in common with the cathode of a second diode 294 of the pair, the anode of the second diode 294 is connected in common with the cathode of the first diode 292.

The second current path comprising the pair of diodes 290 in antiparallel, provides a supplemental or second ESD discharge path. As has already been noted, for some ESD events, such as those complying with the HBM, the first inductive current path may effectively dissipate the ESD charge. However, some ESD events have a higher frequency and thus a faster rise time than that according to the standard HBM. Some such events may be standardised according to a charge device model, CDM. ESD events according to CDM may have pulse width as narrow as 1.5 ns, and in consequence may have rise times as short as 100 or even 50 ps. Such fast rise times induce a high impedance in the first inductive current path, and the high impedance seemed by the ESD charge results in the requirement for an alternative dissipation route. If the isolation switch 160 is in and on-state that is to say conducting, and has a low drain-source voltage in and on state (Rds-on), some of the ESD current may dissipate through the isolation switch 160 and thence to ground 140 via the first coil 172 of the inductive coupler 174, and another part the current flows through the second current path. Alternatively, in the event that the isolation switch is open or in an off state, the second current path provided by the diodes 290 provide the dissipation route for the ESD charge. In particular, irrespective of whether the charge is positive or negative, at the start of the ESD event the magnitude (either positive or negative) of the voltage across the pair of diodes 190 in antiparallel rises, and exceeds 0.6V, at which a voltage a one of the diodes, either first diode 292 or second diode 294 depending on the sign of the ESD charge, will start to conduct to dissipate the charge to ground through the first coil 172 of the inductive coupler 174.

The diodes 292 and 294 may be conventional diodes, provided they are capable of operating at a high frequency (in the order of ns, or 10 s of ns for a typical ESD event which the diodes have to handle), and sufficiently high current-carrying capacity (typically around 2 to 12 A).

An alternative implementation of the circuit block 190 which forms the second current path is a plurality of pairs of diodes connected in antiparallel, as depicted in FIG. 3, which shows a simplified circuit 300 corresponding to part of the circuit of FIG. 1, according to one or more other embodiments. In this FIG. the single pair of diodes 290 connected in antiparallel is replaced by a plurality of such antiparallel pairs, 392, 394, the pairs begin connected in series. In such embodiments, the second current path starts to conduct when the magnitude of the voltage reaches 0.6 V multiplied by N, where N is the number of antiparallel-connected diode pairs connected in series. Thus in the example shown with two pairs, the current path starts to conduct when the voltage across it reaches 2×0.6V that is to say 1.2 V. The skilled person will appreciate that although FIG. 3 shows the series connection of the pairs with a node between each pair, the diodes could equally be arranged such that end diodes have a common connection. In other words there is a series of diodes which conduct in one direction, and that series of diodes is connected in parallel to a series of nodes which conduct in the other direction (the connection between the two series therefore being in “antiparallel”).

FIG. 4 shows a simplified schematic of an electrostatic-discharge-protected, ESD-protected, isolation circuit according to one or more other embodiments. This embodiment is similar to that shown in FIG. 2, except that the isolation switch is between two small value capacitors 462, 464, which are arranged in series with it, and may be included to enable reverse bias of the parasitic junction. The small value capacitors 462, 464 may typically have values between 1 and 50 pF, and in a particular embodiment have values approximately 20 pF. In some embodiments, (not shown), the at least one pair of diodes connected in antiparallel, 290, is connected across the series combination of a first small-value capacitor 462, isolation switch 160 and a second small-value capacitor 464. In other embodiments, as shown in FIG. 4, the at least one pair of diodes connected in antiparallel is connected across only the isolation switch 160. In such embodiments, the second current path, which in this example case comprises a single pair of diodes 290 connected antiparallel, includes both the small value capacitors 462 and 464. The skilled person will appreciate that in other embodiments, the at least one pair of diodes connected in antiparallel includes a plurality of such diodes, as described above with respect to FIG. 3.

The skilled person will appreciate that, in some manufacturing processes, the pair of diodes 290 may be fabricated including a “base” between emitter and collector, and be referred to as “PNP” diodes. In such embodiments, such as that shown in FIG. 4 which includes capacitors 462, 464 in series with, and one on either side of, the isolation switch 160, the capacitors 462, 464 may be used to change the biasing of the emitter and base terminals of the diodes to avoid forward biasing of their base to collector interface.

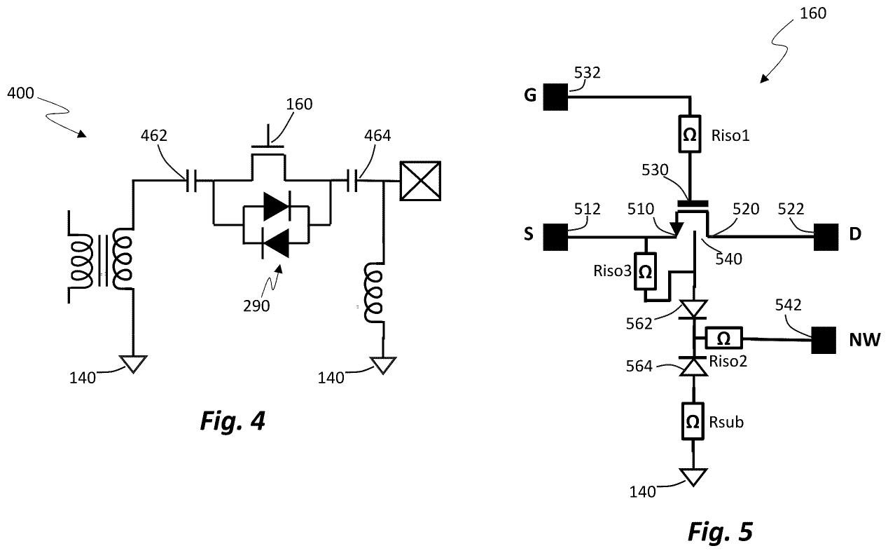

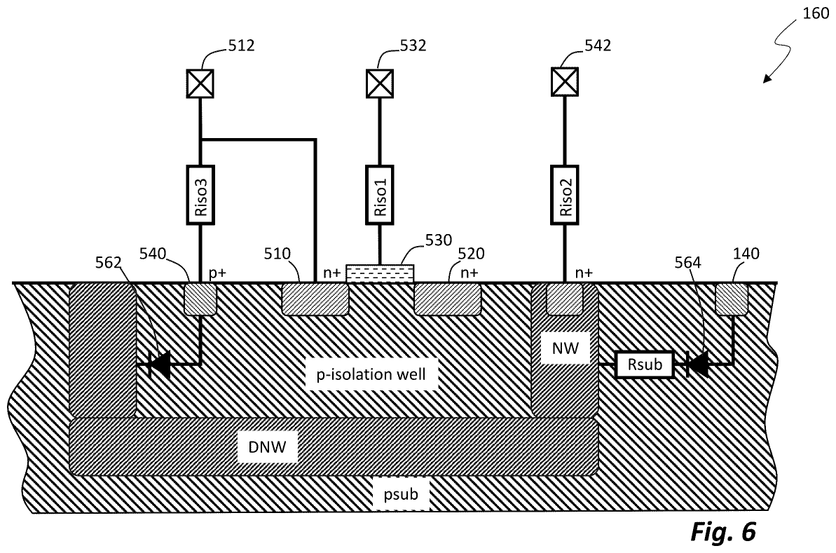

Turning now to FIG. 5 and FIG. 6, FIG. 5 shows, a schematic circuit diagram of an example of an isolation switch 160 according to one or more embodiments, and FIG. 6 shows a schematic cross-section through the isolation switch. The switch is characterised by source 510 and drain 520 connections, together with gate 530 connection, and a body connection 540. The gate 530 is coupled to gate terminal 532 via a resistor Riso1; the body 540 is directly, or indirectly, coupled via resistor Riso3 to the source 510. An isolation terminal 542 NW is connected to the isolation n-well NW, for providing an isolation bias to the switch. There is a parasitic diode 562 (and resistance Riso2) between the isolation terminal 542 and the body, and a parasitic diode 564 (and substrate resistance Rsub) between the isolation terminal 542 and ground 140. The skilled person will be aware that such switches may be made using various advanced structures and technology “nodes”, including less advanced technology such as 40 nm SOI (semiconductor-on-insulator), and more advanced nodes such as 22-12 nm FDSOI (fully depleted SOI), 16 to 2 nm FinFET, etc.: in general, the smaller, or more advanced the node, the more susceptible the isolation switch is to damage through ESD events, and the less feasible it is to provide self-protection. The skilled person will also be aware, that for some technologies and nodes, ESD self-protection of a switch, and in particular an RF switch configured to operate at frequencies at or above, 2.4 GHz, may be through the parasitic-bipolar operation of the switch, and the current capacitor of the parasitic bipolar-operation tends to shrink or reduce, as the node becomes smaller or more advanced. The signal swing at the input and output ports (respectively source terminal 512, coupled to the source 510, and drain terminal 522 coupled to the drain 520) can be in the range of +/−3V (that is to say, a 6V peak-to-peak swing) relative to ground 140, or more, whereas the device itself may be rated as only approximately 1.8 V. The source 510 is coupled to the body through resistor Riso3. Diodes 562 and 564 are parasitic p-n diodes, as is apparent in the cross-section shown in FIG. 6. During RF operation the capacitance between drain (or source) to gate (Cgs or Cgd), and the capacitance between drain (or source) to body (Cdb, and Csb respectively) couples the high swing towards the gate and body keeping the device at safe region. For example, in the case of an RF swing of 10V and a gate voltage of 1V, because of the AC coupling to 530 the gate is elevated by the RF signal (such that, relative to ground 140, it has potential of 1V +/−10 V); at the same time the source (510) has DC bias of 0+−10 V; combining those two voltages results in a Vgs of switch of ˜1V so the transistor is conductive. Conversely, in the cases of an RF swing of 10V and a gate voltage of 0V, because of the AC coupling to 530 the gate is elevated by the RF signal (meaning relative to ground 140 it has potential of 0V +/−10 V); at the same time the source (510) has DC bias of 0+/−10 V; combining those two voltages, results in a Vgs of switch of 0V so the transistor is off or non-conductive.

The illustrations of embodiments described herein are intended to provide a general understanding of the structure of various embodiments, and they are not intended to serve as a complete description of all the elements and features of apparatus and systems that might make use of the structures described herein. Many other embodiments will be apparent to those of skill in the art upon reviewing the above description. Other embodiments may be utilized and derived therefrom, such that structural and logical substitutions and changes may be made without departing from the scope of this disclosure. FIG. s are also merely representational and may not be drawn to scale. Certain proportions thereof may be exaggerated, while others may be minimized. Accordingly, the specification and drawings are to be regarded in an illustrative rather than a restrictive sense.

Although specific embodiments have been illustrated and described herein, it should be appreciated that any arrangement calculated or constructed to achieve the same or a similar purpose may be substituted for the specific embodiments shown. This disclosure is intended to cover any and all adaptations or variations of various embodiments. Combinations of the above embodiments, and other embodiments not specifically described herein, are contemplated by the subject disclosure.

For instance, one or more features or aspects from one or more embodiments can be combined with one or more features or aspects of one or more other embodiments. In one or more embodiments, features that are positively recited can also be negatively recited and excluded from the embodiment with or without replacement by another structural and/or functional feature.

The use of numerical terms to describe a device, component, step or function, such as first, second, third, and so forth, is not intended to describe an order or function unless expressly stated so. The use of the terms first, second, third and so forth, is generally to distinguish between devices, components, steps or functions unless expressly stated otherwise. Additionally, one or more devices or components described with respect to the exemplary embodiments can facilitate one or more functions, where the facilitating (e.g., facilitating access or facilitating establishing a connection) can include less than every step needed to perform the function or can include all of the steps needed to perform the function.

The Abstract of the Disclosure is provided with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment.

1. An electrostatic-discharge-protected, ESD-protected, isolation circuit comprising:
an isolation switch;
an inductive coupler in series with the isolation switch;
an antenna terminal, connected to a ground via the isolation switch and the inductive coupler in series, wherein the inductive coupler is configured to, in response to the switch being in an on-state, provide inductive coupling to a transmitter circuit, and wherein the switch is configured to, in an off-state, galvanically isolate the inductive coupler from the antenna terminal;
and a protection circuit, wherein the protection circuit comprises:
a first inductive current path connected between the antenna terminal and ground, and
a second current path connected in parallel to the switch and between the antenna terminal and the inductive coupler, wherein the second current path is enabled in response to an ESD event at the antenna terminal.

2. The ESD-protected isolation circuit of claim 1, wherein:
the second current path comprises at least one pair of diodes connected in anti-parallel.

3. The ESD-protected isolation circuit of claim 2, wherein:
the at least one pair of diodes connected in anti-parallel comprises a series arrangement of plurality of pairs of diodes connected in anti-parallel.

4. The ESD-protected isolation circuit of claim 1, further comprising:
a first capacitor connected between the antenna terminal and the switch; and
a second capacitor connected between the switch and the inductive coupler.

5. The ESD-protected isolation circuit of claim 2, further comprising:
a first capacitor connected between the antenna terminal and the switch; and
a second capacitor connected between the switch and the inductive coupler.

6. The ESD-protected isolation circuit of claim 5,
wherein the at least one pair of diodes connected in anti-parallel is connected across a path comprising the first capacitor, the switch and the second capacitor.

7. The ESD-protected isolation circuit of claim 5,
wherein the at least one pair of diodes connected in anti-parallel is connected in series with, and between, the first capacitor and the second capacitor.

8. The ESD-protected isolation circuit of claim 2, wherein
the at least one pair of diodes connected in anti-parallel is configured to conduct at a voltage which is less than a break-down voltage of the switch.

9. The ESD-protected isolation circuit of claim 2, wherein
the at least one pair of diodes connected in anti-parallel is configured to conduct a current such that a current through the switch is less than a break-down current of the switch.

10. The ESD-protected isolation circuit of claim 2, wherein the at least one pair of diodes connected in anti-parallel is integrated into a same device as the isolation switch.

11. The ESD-protected isolation circuit of claim 1, wherein
the first inductive current path comprises:
a further inductive coupler connected to between the ground and a first node, A,
and a series arrangement of two inductors having a second node B therebetween and being connected between the further inductive coupler and the antenna terminal;
wherein the further inductive coupler is configured to be inductively coupled to a receiver circuit; and
wherein the ESD-protected isolation circuit further comprises a shunt switch connected between the node and ground, and configured to bypass the further inductive coupler in response to the isolation switch being in the on-state.

12. The ESD-protected isolation of circuit 11, further comprising
an ESD discharge circuit connected between the second node, B, and ground.

13. The ESD-protected isolation circuit of claim 1, wherein
the inductive coupler is a balun.

14. The ESD-protected isolation circuit of claim 13, wherein
the balun is configured to transmit a radio frequency, RF, output voltage, from the transmitter circuit, having a peak-to-peak voltage swing of at least 6V.

15. The ESD-protected isolation circuit of claim 1, wherein
the isolation switch is a field effect transistor, FET.

16. The ESD-protected isolation circuit of claim 15, wherein
the isolation switch is a fully depleted semiconductor-on-insulator FET, in a technology node which is no greater than 22 nm.

17. The ESD-protected isolation circuit of claim 15, wherein
the isolation switch is a FinFET, in a technology node which is no greater than 16 nm.

18. The ESD-protected isolation circuit of claim 1 wherein
the first inductive current path, the second current path are the only ESD current paths to ground.

19. The ESD-protected isolation circuit of claim 1, wherein the first inductive current path is coupled to a receiver circuit.

20. The ESD-protected isolation circuit of claim 19, wherein
the receiver circuit is a single-ended circuit and the first inductive current path includes a low-noise amplifier which is a part of the first inductive current path.
